(19) United States
(12) Patent Application Publication
(10) Pub. No.: US 2022/0283674 A1
(43) Pub. Date: Sep. 8, 2022

(54) IN-CELL TOUCH PANEL AND METHOD FOR PRODUCING IN-CELL TOUCH PANEL

(71) Applicant: SHARP KABUSHIKI KAISHA, Sakai City (JP)

(72) Inventors: MASAKI MAEDA, Sakai City (JP); TOHRU DAITOH, Sakai City (JP); HAJIME IMAI, Sakai City (JP); YOSHIHITO HARA, Sakai City (JP); TERUYUKI UEDA, Sakai City (JP); YOSHIHARU HIRATA, Sakai City (JP); TATSUYA KAWASAKI, Sakai City (JP)

(21) Appl. No.: 17/684,024

(22) Filed: Mar. 1, 2022

Related U.S. Application Data
(60) Provisional application No. 63/155,614, filed on Mar. 2, 2021.

(51) Int. Cl. G06F 3/044; H01L 27/12; G02F 1/1333; G02F 1/1368; G02F 1/1362; G02F 1/1343

(52) U.S. Cl. CPC G06F 3/0446; H01L 27/124; H01L 27/1259; G02F 1/13338; G02F 1/1368; G02F 1/136295; G02F 1/133345; G02F 1/134309; G02F 1/13439; G06F 2203/04103

(57) ABSTRACT

An in-cell touch panel includes a plurality of source lines, a source redundant line, a touch sensor line formed in the same layer as the plurality of source lines or the source redundant line, an organic insulating layer formed in a layer above the touch sensor line, and a common electrode formed in a layer above the organic insulating layer. A contact hole in which part of the common electrode is arranged is formed in the organic insulating layer above the touch sensor line, and the common electrode is connected to the touch sensor line via the contact hole.

### CROSS-REFERENCE TO RELATED APPLICATIONS

This application claims the benefit of priority to U.S. Provisional Application No. 63/155,614 filed on Mar. 2, 2021. The entire contents of the above-identified application are hereby incorporated by reference.

### TECHNICAL FIELD

The disclosure relates to an in-cell touch panel and a method for manufacturing the in-cell touch panel.

### BACKGROUND

There have been known in-cell touch panels and methods for manufacturing the in-cell touch panels. Such an in-cell touch panel and a method for manufacturing the in-cell touch panel are disclosed in, for example, JP 2020-140075 A.

The above JP 2020-140075 A discloses an in-cell touch panel including a thin film transistor, a gate line, a data line, an organic insulating film, a touch line, a pixel electrode, and a common electrode. The data line is formed in a layer above the gate line. The organic insulating film is formed in a layer above the data line and is thicker. The touch line is formed in a layer above the organic insulating film. The pixel electrode and the common electrode are formed in layers above the touch line.

### SUMMARY

Here, in the in-cell touch panel as described in the above JP 2020-140075 A, it is conceivable to form a data redundant line in a layer above the data line so that the data signal can be supplied to the thin film transistor even when the data line is disconnected. In this case, there is a problem that the number of steps for manufacturing the in-cell touch panel increases in order to form the data redundant line (source redundant line).

The disclosure has been made to solve the above problem, and an object of the disclosure is to provide an in-cell touch panel and a method for manufacturing the in-cell touch panel that do not increase the number of manufacturing steps even when the source redundant line is formed.

In order to achieve the above-described object, the in-cell touch panel according to a first aspect includes a plurality of thin film transistors, a plurality of source lines configured to respectively supply source signals to the plurality of thin film transistors, a source redundant line formed in the same layer as the plurality of source lines or a layer above the plurality of source lines and connected to at least one of the plurality of source lines, a touch sensor line formed in the same layer as either the plurality of source lines or the source redundant line, an organic insulating layer formed in a layer above the source redundant line and above the touch sensor line, a plurality of pixel electrodes formed in a layer above the organic insulating layer, and a common electrode formed in a layer above the organic insulating layer, and configured to function as a touch electrode and also function as a counter electrode that forms an electrical field together with the plurality of pixel electrodes, in which a contact hole in which part of the common electrode is arranged is formed in the organic insulating layer above the touch sensor line, and the common electrode is connected to the touch sensor line via the contact hole.

A method for manufacturing an in-cell touch panel according to a second aspect includes forming a plurality of source lines that respectively supply source signals to a plurality of thin film transistors on a substrate, forming a source redundant line connected to at least one of the plurality of source lines, forming a touch sensor line in the same layer as the plurality of source lines in the forming of the plurality of source lines, or forming a touch sensor line in the same layer as the source redundant line in the forming of the source redundant line, forming an organic insulating layer in a layer above the touch sensor line and the source redundant line, forming a contact hole in the organic insulating layer above the touch sensor line, forming a plurality of pixel electrodes in a layer above the organic insulating layer, and forming a common electrode, which functions as a touch electrode and also functions as a counter electrode that forms an electrical field together with the plurality of pixel electrodes, in a layer above the organic insulating layer with at least part of the common electrode arranged in the contact hole.

According to the configuration of the first or the second aspect described above, the touch sensor line is formed in the same layer as the plurality of source lines or the source redundant line, so the touch sensor line and the plurality of source lines or the source redundant line can be formed in the same step. As a result, it is possible to provide an in-cell touch panel and a method for manufacturing the in-cell touch panel that do not increase the number of manufacturing steps even when the source redundant line is formed.

### BRIEF DESCRIPTION OF DRAWINGS

The disclosure will be described with reference to the accompanying drawings, wherein like numbers reference like elements.

FIG. 1 is a block diagram illustrating a schematic configuration of a display device according to a first embodiment.

FIG. 2 is a cross-sectional view illustrating a configuration of an in-cell touch panel.

FIG. 3 is a cross-sectional view illustrating a configuration of an active matrix substrate according to the first embodiment.

FIG. 4 is a schematic plan view for explaining the configuration of the active matrix substrate.

FIG. 5 is a circuit diagram for explaining the connection of a thin film transistor to a source line and a gate line.

FIG. 6 is a cross-sectional view of the thin film transistor.

FIG. 7 is a schematic plan view for explaining the connection between a common electrode and a touch sensor line.

FIG. 8 is an enlarged view of a region A1 in FIG. 7.

FIG. 9 is a flowchart for explaining a process for manufacturing the in-cell touch panel according to the first embodiment.

FIG. 10 is a diagram of a modified example of the first embodiment.

FIG. 11 is a cross-sectional view (1) of part of a display device (in-cell touch panel) of a second embodiment.

FIG. 12 is a cross-sectional view (2) of part of the display device (in-cell touch panel) of the second embodiment.

FIG. 13 is a cross-sectional view (1) of part of an in-cell touch panel according to a modified example of the second embodiment.

FIG. 14 is a cross-sectional view (2) of part of the in-cell touch panel according to the modified example of the second embodiment.

FIG. 15 is a plan view of part of the in-cell touch panel according to the modified example of the second embodiment.

### DESCRIPTION OF EMBODIMENTS

Embodiments of the disclosure will be described below with reference to the drawings. Note that the disclosure is not limited to the following embodiments, and appropriate design changes can be made within a scope that satisfies the configuration of the disclosure. Further, in the description below, the same reference signs are used in common among the different drawings for portions having the same or similar functions, and descriptions of repetitions thereof will be omitted. Further, the configurations described in the embodiments and the modified examples may be combined or modified as appropriate within a range that does not depart from the gist of the disclosure. Further, for ease of explanation, in the drawings referenced below, the configuration is simplified or schematically illustrated, or a portion of the components are omitted. Further, dimensional ratios between components illustrated in the drawings are not necessarily indicative of actual dimensional ratios.

### First Embodiment

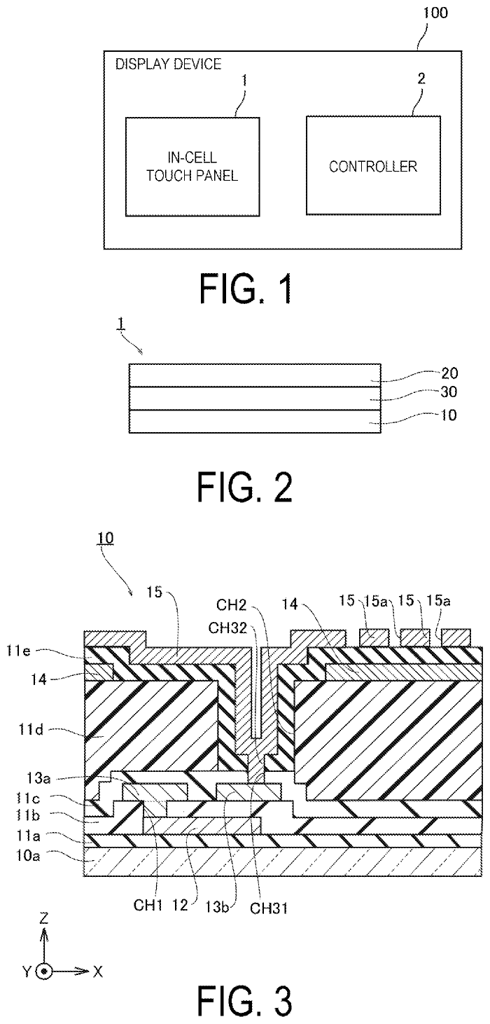

FIG. 1 is a block diagram illustrating the configuration of a display device 100 according to a first embodiment. As illustrated in FIG. 1, the display device 100 includes an in-cell touch panel 1 and a controller 2. The in-cell touch panel 1 is a full in-cell touch panel. In addition, the in-cell touch panel 1 has a function of detecting a touch by an indicator (finger or pen), and also has a function of displaying a video or an image as a display panel. The controller 2 each executes control processing in the display device 100 based on a touch position acquired from the in-cell touch panel 1.

FIG. 2 is a cross-sectional view schematically illustrating a structure of the in-cell touch panel 1. As illustrated in FIG. 2, the in-cell touch panel 1 includes an active matrix substrate 10, a counter substrate 20 (color filter substrate), and a liquid crystal layer 30. The liquid crystal layer 30 is sandwiched between the active matrix substrate 10 and the counter substrate 20. A color filter (not illustrated) is placed in the counter substrate 20.

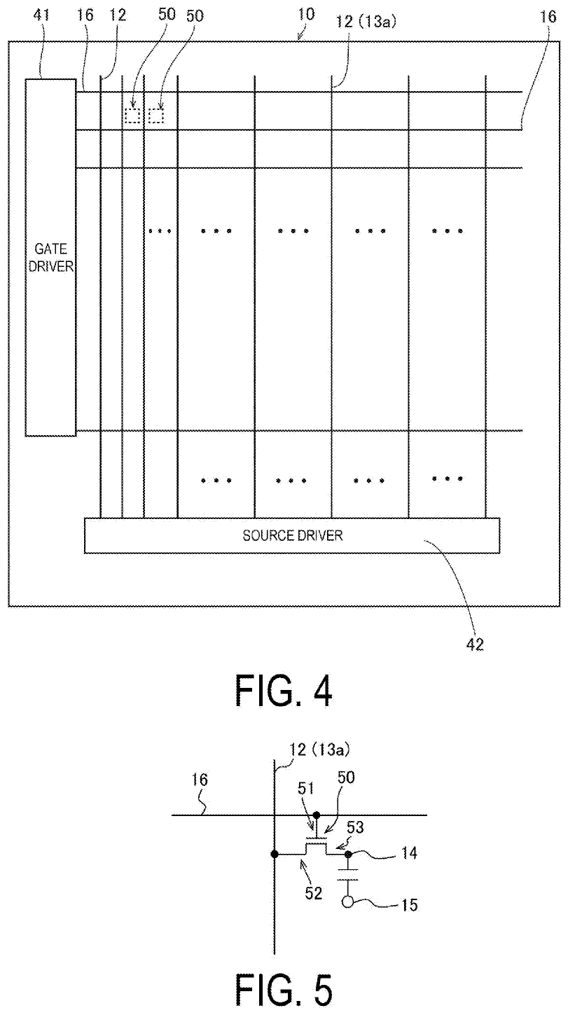

FIG. 3 is a cross-sectional view of the active matrix substrate 10. As illustrated in FIG. 3, in the active matrix substrate 10, from a side opposite to the liquid crystal layer 30, a glass substrate 10a, a gate line 16 (see FIG. 4), a gate insulating layer 11a, a source line 12, a first insulating layer lib, a source redundant line 13a and a touch sensor line 13b, a second insulating layer 11c, an organic insulating layer 11d, a pixel electrode 14, a third insulating layer 11e, and a common electrode 15 are formed in this order.

Further, in the in-cell touch panel 1, a driving method of liquid crystal molecules contained in the liquid crystal layer 30 is a transverse electrical field driving method. The pixel electrode 14 and the common electrode 15 for forming an electrical field are formed in the active matrix substrate 10. The common electrode 15 is provided in common for a plurality of pixel electrodes 14. As illustrated in FIG. 3, the common electrode 15 has a plurality of slits 15a.

FIG. 4 is a schematic plan view for explaining the arrangement of the source line 12 and the gate line 16. As illustrated in FIG. 4, the active matrix substrate 10 is provided with a gate driver 41 and a source driver 42. A plurality of gate lines 16 and a plurality of source lines 12 intersect each other to form a lattice pattern in a plan view. The plurality of gate lines 16 are connected to the gate driver 41. Further, the plurality of source lines 12 are connected to the source driver 42. The gate driver 41 and the source driver 42 are constituted of, for example, integrated circuits. The gate driver 41 supplies gate signals (scanning signals) sequentially to the plurality of gate lines 16. The source driver 42 supplies a source signal (data signal) to each of the plurality of source lines 12. A thin film transistor 50 is provided in a region surrounded by the plurality of gate lines 16 and the plurality of source lines 12.

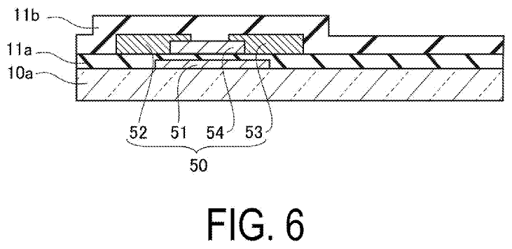

FIG. 5 is a schematic circuit diagram for explaining the connection of the thin film transistor 50 to the gate line 16 and the source line 12. FIG. 6 is a cross-sectional view illustrating a configuration of the thin film transistor 50. As illustrated in FIG. 5, a gate electrode 51 of the thin film transistor 50 is connected to the gate line 16, and a source electrode 52 of the thin film transistor 50 is connected to the source line 12. Further, a drain electrode 53 of the thin film transistor 50 is connected to the pixel electrode 14. Furthermore, the pixel electrode 14 forms an electrostatic capacitance together with the common electrode 15.

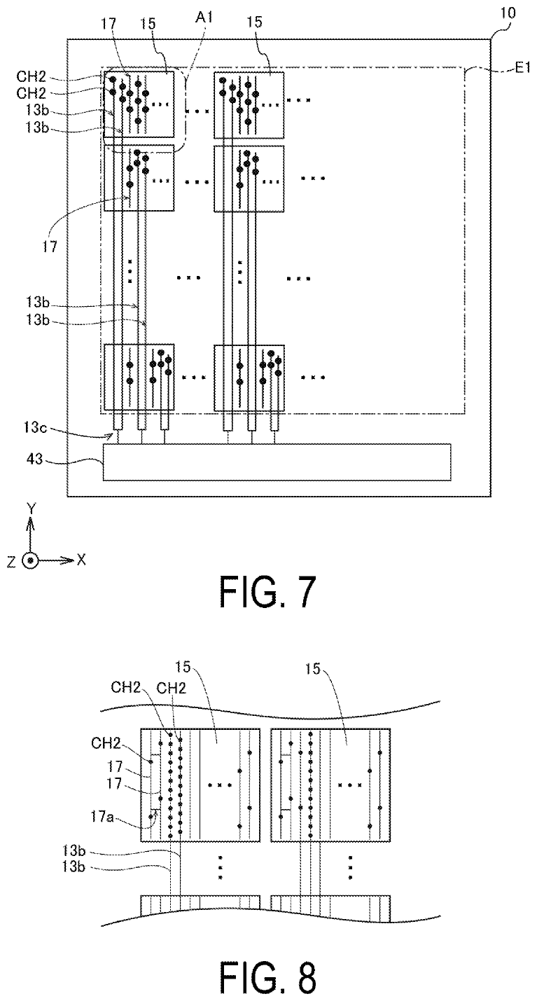

FIG. 7 is a schematic plan view for explaining an arrangement relationship between the common electrode 15, the touch sensor line 13b, and a touch detection driver 43. FIG. 8 is an enlarged view of a region A1 in FIG. 7. Note that the illustrations in FIGS. 7 and 8 omit some parts of the in-cell touch panel 1. As illustrated in FIG. 7, the active matrix substrate 10 is provided with the touch detection driver 43. The touch detection driver 43 includes an integrated circuit that performs control processing related to touch detection. Further, a plurality of touch sensor lines 13b are connected to the touch detection driver 43. Each of the plurality of touch sensor lines 13b extends in the same layer in the Y direction (parallel to the direction in which the source line 12 and the source redundant line 13a extend). With this configuration, the source redundant line 13a and the touch sensor line 13b do not intersect each other, so the source redundant line 13a and the touch sensor line 13b can be easily formed in the same layer.

Further, the plurality of touch sensor lines 13b are connected to each common electrode 15. With this configuration, the common electrode 15 functions as a touch electrode, and also functions as a counter electrode that forms an electrical field together with the plurality of pixel electrodes 14. In the first embodiment, two touch sensor lines 13b are connected to one common electrode 15. These two touch sensor lines 13b are connected to each other by a connecting part 13c outside (on the touch detection driver 43 side) the display region E1 (the region in which the pixel electrodes 14 are arranged). That is, one of the two touch sensor lines 13b functions as a touch sensor redundant line. According to this configuration, even when one of the two touch sensor lines 13b is disconnected, touch detection can be performed using the other touch sensor line 13b. Further, since the plurality of touch sensor lines 13b are connected to one common electrode 15, the dimension in the width direction of one touch sensor line 13b can be reduced, and the dimension of the connection part (contact hole CH2) between the touch sensor line 13b and the common electrode 15 can also be reduced. As a result, the light transmittance of the in-cell touch panel 1 can be improved by reducing the width of each touch sensor line 13b and the dimension of the connection part. The touch sensor line 13b is configured as a layered film of Cu (copper) and a transparent conductive film (ITO: indium-tin oxide).

The two touch sensor lines 13b are arranged adjacent to each other in a plan view. According to this configuration, the two touch sensor lines 13b can be connected to each other more easily by the connecting part 13c than when the two touch sensor lines are separated. Further, each of the two touch sensor lines 13b is connected to the common electrode 15 via a plurality of contact holes CH2. According to this configuration, the size of each of the plurality of contact holes CH2 can be reduced, so the light transmittance of the in-cell touch panel 1 can be improved.

As illustrated in FIG. 8, a plurality of dummy lines 17 are arranged in the same layer as the touch sensor line 13b at positions adjacent to the touch sensor line 13b. The dummy line 17 extends parallel to the touch sensor line 13b and is not directly connected to the touch detection driver 43. Note that the state “the dummy line 17 is not directly connected to the touch detection driver 43” includes, for example, a state in which the dummy line 17 is electrically connected to the touch detection driver 43 via the common electrode 15 and the touch sensor line 13b. Further, the touch sensor line 13b is arranged across the plurality of common electrodes 15, while the dummy line 17 is arranged on the single common electrode 15. The common electrode 15 and the plurality of dummy lines 17 connected to this common electrode 15 can be electrically independent of the dummy lines 17 on the other common electrodes 15.

The dummy line 17 is constituted as, for example, a layered film of Cu (copper) and ITO. Cu has a resistance value smaller than that of ITO used for the common electrode 15. Further, the dummy lines 17 adjacent to each other are connected by a connecting part 17a. As a result, when the dummy line 17 and the common electrode 15 are regarded as one segment, the resistance value of the segment can be reduced compared to a case in which the dummy line 17 is not provided. Further, as illustrated in FIG. 7, the plurality of dummy lines 17 are arranged on the common electrode 15 in parallel with the touch sensor line 13b at equal intervals. According to this, in any of the common electrodes 15, the touch sensor line 13b and the plurality of dummy lines 17 are arranged in parallel in the same way, so the shape of the light transmitting portion between the touch sensor line 13b and the dummy line 17 and the shape of the light transmitting portion between the plurality of dummy lines 17 are equal to each other. As a result, an optical difference (transmittance change) of each line (RGB pixel) can be eliminated, and a color shift can be prevented.

### Configuration of Each Layer in Active Matrix Substrate

As illustrated in FIG. 6, the gate electrode 51 of the thin film transistor 50 is formed on the glass substrate 10a. The gate insulating layer 11a is formed on the glass substrate 10a so as to cover the gate electrode 51 and the gate line 16 (see FIG. 4). A semiconductor layer 54 is formed on the gate insulating layer 11a. The source electrode 52 and the drain electrode 53 each are formed on the gate insulating layer 11a so as to cover part of the semiconductor layer 54. The gate electrode 51, the source electrode 52, and the drain electrode 53 are constituted of, for example, a metal film or a transparent conductive film (e.g., ITO). The semiconductor layer 54 is constituted of, for example, an oxide semiconductor containing indium (In), gallium (Ga), zinc (Zn), and oxygen (O). The gate insulating layer 11a is formed of, for example, an inorganic insulating film, specifically, made of silicon nitride (SiNx) or silicon oxide (SiO₂). Further, the gate line 16 is formed of, for example, a metal film.

As illustrated in FIG. 3, the source line 12 is formed on the gate insulating layer 11a and is formed of a metal film. The first insulating layer 11b is formed so as to cover the source line 12. As illustrated in FIG. 6, the first insulating layer 11b is formed of, for example, an inorganic insulating film, specifically, made of silicon nitride (SiNx) or silicon oxide (SiO₂). In the first insulating layer 11b, a contact hole CH1 in which part of the source redundant line 13a, which is formed in the same layer as the touch sensor line 13b, is provided, is arranged above the source line 12.

Then, the source redundant line 13a and the touch sensor line 13b are formed in a layer above the first insulating layer 11b. Both the source redundant line 13a and the touch sensor line 13b are formed so as to extend in the Y direction, and are arranged adjacent to each other with a gap in the X direction. Part of the source redundant line 13a is formed in the contact hole CH1, and is connected to the source line 12 via the contact hole CH1. The source redundant line 13a and the touch sensor line 13b may each be made of a metal, such as titanium (Ti) or copper (Cu), or may be formed by layering these materials.

Then, the second insulating layer 11c is formed so as to cover the source redundant line 13a and the touch sensor line 13b. In the second insulating layer 11c above the touch sensor line 13b, a contact hole CH31 is formed in which part of the common electrode 15 is arranged. The second insulating layer 11c is formed of an inorganic insulating film, for example, made of silicon nitride (SiNx) or silicon oxide (SiO₂).

As illustrated in FIG. 3, the organic insulating layer 11d is formed so as to cover the second insulating layer 11c. Here, the film thickness of the organic insulating layer 11d is larger than both the film thickness of the second insulating layer 11c and the film thickness of the third insulating layer lie which will be described later. This makes it possible to reduce the parasitic capacitance between the source line 12 and the common electrode 15. Further, in the organic insulating layer 11d above the touch sensor line 13b, a contact hole CH2 in which part of the common electrode 15 and part of the third insulating layer lie are arranged is formed.

The pixel electrode 14 is formed in a layer above the organic insulating layer 11d. The pixel electrode 14 may be formed of, for example, a transparent conductive film (e.g., ITO) or may be formed of a reticular metal (metal mesh). Then, the third insulating layer 11e is formed so as to cover the pixel electrode 14. Part of the third insulating layer 11e is arranged in the contact hole CH2 in the organic insulating layer 11d. A contact hole CH32 is formed in the part of the third insulating layer lie that is arranged in the contact hole CH2 above the touch sensor line 13b. The contact hole CH32 is continuous with the contact hole CH31 in the second insulating layer 11c. The third insulating layer lie is formed of an inorganic insulating film, for example, made of silicon nitride (SiNx) or silicon oxide (SiO₂).

The common electrode 15 is formed in a layer above the third insulating layer lie. The part of the common electrode 15 is formed in the contact hole CH2 and also in the contact holes CH31 and CH32. The common electrode 15 is connected to the touch sensor line 13b via the contact holes CH2, CH31, and CH32. The common electrode 15 may be formed of a transparent conductive film (e.g., ITO) or may be formed of a reticular metal (metal mesh).

According to the above configuration, the touch sensor line 13b is formed in the same layer as the source redundant line 13a, so that the touch sensor line 13b and the source redundant line 13a can be formed in the same step as described later. As a result, even when the source redundant line 13a is formed, the number of manufacturing steps does not increase (the number of masks does not increase). Thus, the yield of the in-cell touch panel 1 can be improved by forming the source redundant line 13a without increasing the number of steps for manufacturing the in-cell touch panel 1.

In addition, when the touch sensor line and the pixel electrode are formed in the same layer, it is necessary to secure a relatively large insulation distance between the touch sensor line and the pixel electrode in the plane direction. In contrast, according to the above configuration, the touch sensor line 13b is arranged in a layer (different layer) below the pixel electrode 14, so the distance between the touch sensor line 13b and the pixel electrode 14 in the plane direction can be reduced. Thus, the light blocking portion arranged between the pixel electrodes 14 can be reduced in a plan view, so the aperture ratio of the in-cell touch panel 1 can be increased. In addition, by increasing the aperture ratio, the light transmittance of the in-cell touch panel 1 is improved, so the in-cell touch panel 1 can be made higher in definition and can be driven at a higher frequency.

### Method for Manufacturing In-cell Touch Panel

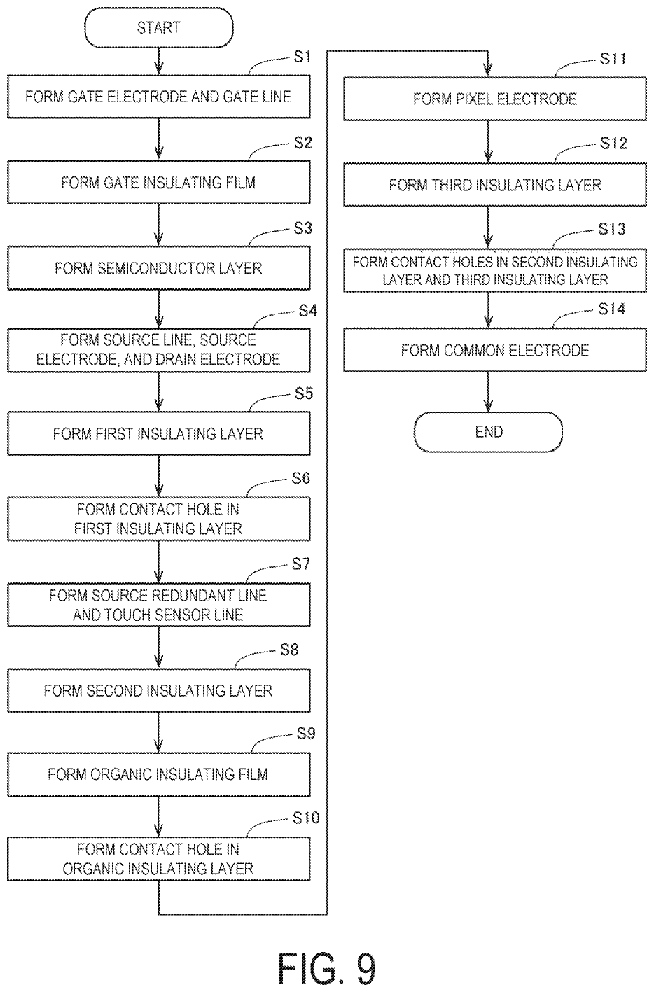

Next, with reference to FIG. 9, a method for manufacturing the in-cell touch panel 1 according to the first embodiment will be described. FIG. 9 illustrates a flowchart of the process for manufacturing the in-cell touch panel 1.

In step S1, as illustrated in FIG. 6, the gate electrode 51 and the gate line 16 (see FIG. 4) are formed on the glass substrate 10a. In step S2, the gate insulating layer 11a is formed so as to cover the gate electrode 51 and the gate line 16.

In step S3, the semiconductor layer 54 (see FIG. 6) is formed in the layer above the gate insulating layer 11a, and in step S4, the source electrode 52 and the drain electrode 53 are formed on the gate insulating layer 11a in the layer above the semiconductor layer 54. In step S4, as illustrated in FIG. 3, the source line 12 is formed on the gate insulating layer 11a.

In step S5, the first insulating layer 11b is formed so as to cover the source line 12, the source electrode 52, and the drain electrode 53. In step S6, the contact hole CH1 is formed in the first insulating layer 11b above the source line 12.

In step S7, the source redundant line 13a and the touch sensor line 13b are formed on the first insulating layer 11b. At least the source redundant line 13a of the source redundant line 13a and the touch sensor line 13b is formed above the source line 12. In step S7, part of the source redundant line 13a is arranged in the contact hole CH1, and the source redundant line 13a and the source line 12 are connected to each other.

In step S8, the second insulating layer 11c is formed so as to cover the source redundant line 13a and the touch sensor line 13b. In step S9, the organic insulating layer 11d is formed so as to cover the second insulating layer 11c. Then, in step S10, the contact hole CH2 is formed in the organic insulating layer 11d above the touch sensor line 13b.

In step S11, the pixel electrode 14 is formed on the organic insulating layer 11d. Then, in step S12, the third insulating layer lie is formed so as to cover the pixel electrode 14. In step S12, the part of the third insulating layer lie is arranged in the contact hole CH2. Then, in step S13, the contact hole CH31 is formed in the second insulating layer 11c above the touch sensor line 13b, and the contact hole CH32 is formed in the third insulating layer lie above the touch sensor line 13b.

In step S14, the common electrode 15 is formed in the layer above the third insulating layer lie. In step S14, part of the common electrode 15 is arranged in the contact holes CH2, CH31, and CH32. As a result, the common electrode 15 and the touch sensor line 13b are connected to complete the active matrix substrate 10. Subsequently, the active matrix substrate 10 is combined with the counter substrate 20 and the liquid crystal layer 30 to complete the in-cell touch panel 1.

According to the above manufacturing method, the touch sensor line 13b and the source redundant line 13a can be formed in the same step (step S7), so the number of manufacturing steps is not increased even when the source redundant line 13a is formed.

### Modified Example of First Embodiment

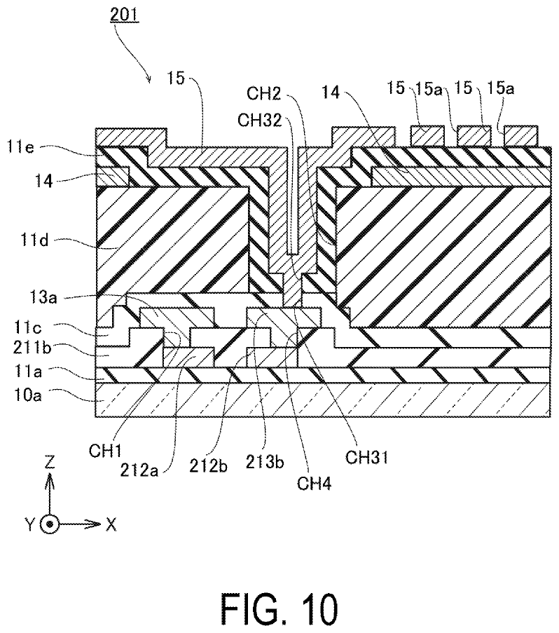

Next, with reference to FIG. 10, a configuration and a method for manufacturing an in-cell touch panel 201, which is a modified example of the in-cell touch panel 1 according to the first embodiment, will be described. In the in-cell touch panel 201, in addition to the configuration of the first embodiment, a touch sensor redundant line 212b is formed in the same layer as a source line 212a. That is, the touch sensor redundant line 212b is formed in a layer below a touch sensor line 213b. The touch sensor line 213b and the touch sensor redundant line 212b are connected via a contact hole CH4 provided in a first insulating layer 211b. The touch sensor redundant line 212b is formed in the same step as step S4 in which the source line 212a is formed in the manufacturing method of the first embodiment. The contact hole CH4 is formed in the same step as step S6 in which the contact hole CH1 is formed. Thus, the number of steps for manufacturing the in-cell touch panel 201 is equal to the number of steps for manufacturing the in-cell touch panel 1 according to the first embodiment.

According to the configuration of this modified example, even when the touch sensor line 213b is disconnected, the touch sensor redundant line 212b can be used for touch detection. Then, the touch sensor redundant line 212b is formed in the same layer as the plurality of source lines 212a, so the touch sensor redundant line 212b can be formed in the step of forming the plurality of source lines 212a. As a result, the touch sensor redundant line 212b can be formed without increasing the number of steps for manufacturing the in-cell touch panel 201.

### Second Embodiment

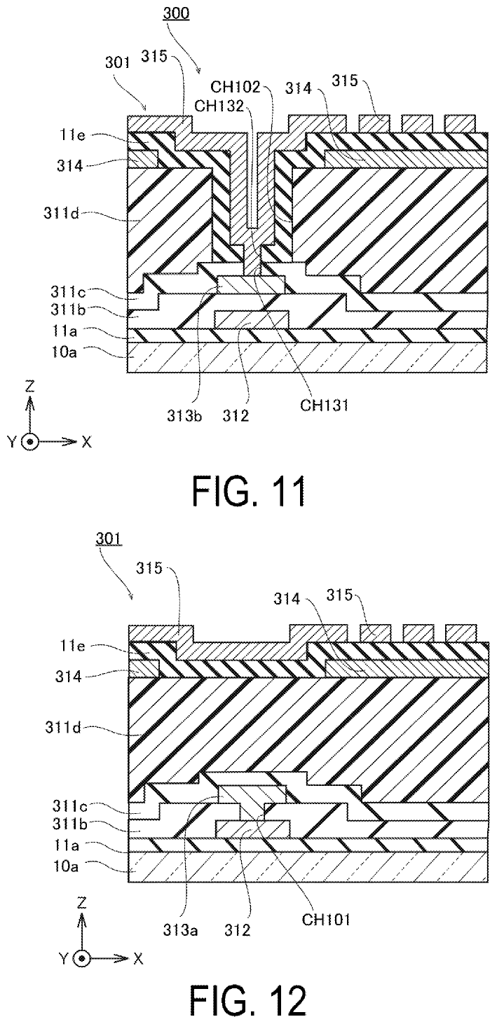

Next, a configuration of the display device 300 of a second embodiment will be described with reference to FIGS. 11 and 12. In the display device 100 of the first embodiment, the source redundant line 13a and the touch sensor line 13b are arranged side by side above the one source line 12, but in the display device 300 of the second embodiment, of a plurality of source lines 312, a source redundant line 313a is not provided above the source line 312 in which a touch sensor line 313b is provided, and the source redundant line 313a is provided above the source line 312 in which the touch sensor line 313b is not provided. Note that, in the following description, when the same reference numerals as in the first embodiment are used, the same configurations as in the first embodiment are indicated, and reference is made to the preceding description unless otherwise described.

### Configuration of Display Device According to Second Embodiment

FIG. 11 is a cross-sectional view of an in-cell touch panel 301 of the display device 300 in which the touch sensor line 313b is provided. FIG. 12 is a cross-sectional view of the in-cell touch panel 301 of the display device 300 in which the touch sensor line 313b is not provided. As illustrated in FIGS. 11 and 12, in the in-cell touch panel 301, the plurality of source lines 312 are formed on the gate insulating layer 11a. In a portion illustrated in FIG. 11, the touch sensor line 313b is formed above the source line 312. In a portion illustrated in FIG. 12, the source redundant line 313a is formed above the source line 312. The source line 312 and the source redundant line 313a are connected via a contact hole CH101 formed in a first insulating layer 311b. The source redundant line 313a is formed in the same layer as the touch sensor line 313b, and is formed in the same step.

As illustrated in FIG. 11, a contact hole CH131 is formed in a second insulating layer 311c that covers the touch sensor line 313b. A contact hole CH102 is formed in an organic insulating layer 311d above the touch sensor line 313b. A contact hole CH132 is formed in a third insulating layer lie that covers a pixel electrode 314. A common electrode 315 is connected to the touch sensor line 313b via the contact holes CH102, CH131, and CH132.

According to the configuration of the second embodiment described above, either the touch sensor line 313b or the source redundant line 313a is arranged above each source line 312. As a result, the dimension in the width direction of each source line 312 can be reduced as compared with a case in which both the touch sensor line 13b and the source redundant line 13a are arranged above each source line 12 as in the first embodiment. As a result, the light transmittance of the in-cell touch panel 301 can be improved. That is, the configuration of the first embodiment is suitable for a large in-cell touch panel, and the configuration of the second embodiment is suitable for a small in-cell touch panel. Further, the other configurations, manufacturing method, and effects of the display device 300 according to the second embodiment are the same as those of the display device 100 according to the first embodiment.

### Modified Example of Second Embodiment

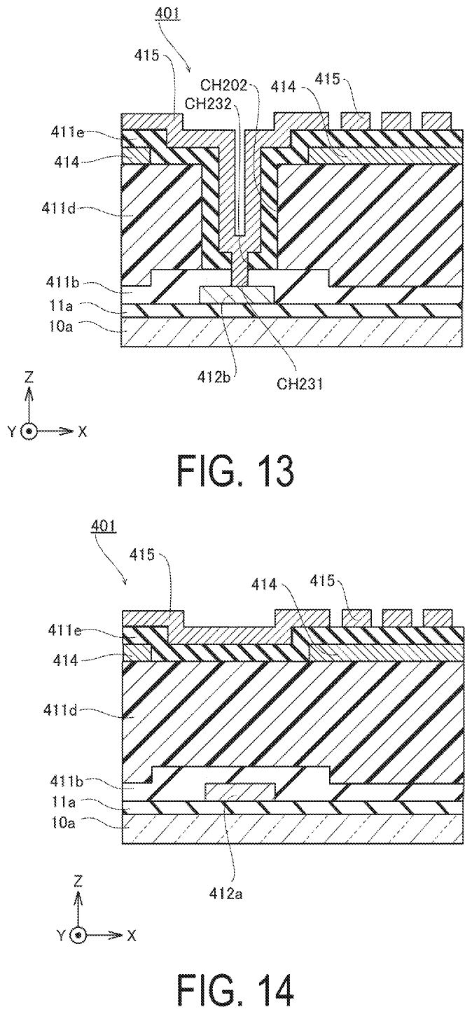

Next, with reference to FIGS. 13 to 15, a configuration and a method for manufacturing an in-cell touch panel 401, which is a modified example of the second embodiment, will be described. Unlike the configuration of the second embodiment described above, the in-cell touch panel 401 includes a touch sensor line 412b formed in the same layer as a source line 412a, and the touch sensor line 412b also functions as a source redundant line. That is, the touch sensor line 412b is formed in a layer below a first insulating layer 411b, and the touch sensor line 412b and the source line 412a are connected to each other.

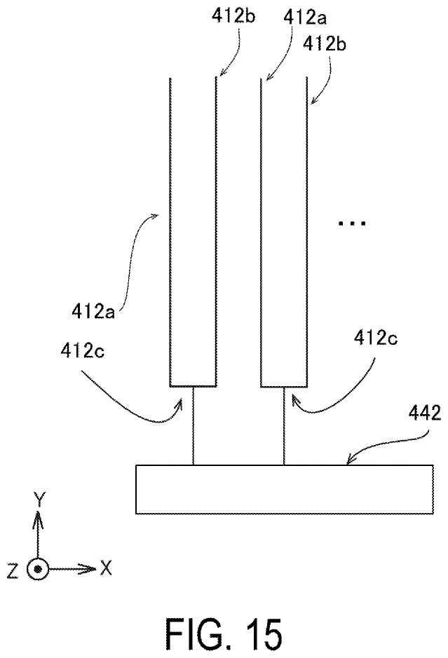

As illustrated in FIG. 13, a common electrode 415 and the touch sensor line 412b are connected to each other via a contact hole CH231 in the first insulating layer 411b, a contact hole CH232 in a third insulating layer 411e, and a contact hole CH202 in an organic insulating layer 411d. The touch sensor line 412b is formed in a layer below a pixel electrode 414. As illustrated in FIG. 14, the source line 412a is formed in the same layer as the touch sensor line 412b. As illustrated in FIG. 15, a driver IC 442 is connected to the source line 412a and the touch sensor line 412b. That is, the driver IC 442 has functions of a source driver and a touch detection driver. Further, the source line 412a and the touch sensor line 412b are connected at a connecting part 412c, and the touch sensor line 412b functions as a source redundant line even when the source line 412a is disconnected. The touch sensor line 412b is formed in a step in which the source line 412a is formed.

The configuration of the modified example also makes it possible to reduce the distance between the touch sensor line 412b and the pixel electrode 414 in the plane direction, since the touch sensor line 412b is arranged in a layer below the pixel electrode 414. Thus, the light blocking portion arranged between the pixel electrodes 414 can be reduced in a plan view, so the aperture ratio of the in-cell touch panel 401 can be increased. In addition, by increasing the aperture ratio, the light transmittance of the in-cell touch panel 401 is improved, so the in-cell touch panel 401 can be made higher in definition and can be driven at a higher frequency.

### Modified Example

Embodiments have been described above, but the embodiments described above are merely examples for implementing the disclosure. Thus, the disclosure is not limited to the embodiments described above and can be implemented by modifying the embodiments described above as appropriate without departing from the scope of the disclosure.

(1) In the above first or second embodiment, an example in which the source redundant line and the touch sensor line are arranged in parallel in a plan view is illustrated, but the disclosure is not limited to this example. The source redundant line and the touch sensor line may not be parallel to each other in a plan view.

(2) In the above first or second embodiment, an example in which one source redundant line or one touch sensor line is arranged above one source line is illustrated, but the disclosure is not limited to this example. For example, a plurality of source redundant lines or a plurality of touch sensor lines may be arranged above one source line.

(3) In the above first or second embodiment, an example in which two touch sensor lines are connected to each common electrode is illustrated, but the disclosure is not limited to this example. For example, one touch sensor line may be connected to each common electrode, or three or more touch sensor lines may be connected to each common electrode.

(4) In the above first or second embodiment, an example in which two touch sensor lines connected to each common electrode are arranged adjacent to each other is illustrated, but the disclosure is not limited to this example. For example, a dummy line may be arranged between the two touch sensor lines.

(5) In the above first or second embodiment, an example in which the common electrode and the touch sensor line are connected as a plurality of locations is illustrated, but the disclosure is not limited to this example. For example, the common electrode and the touch sensor line may be connected at a single location.

The in-cell touch panel and the method for manufacturing the in-cell touch panel described above may be explained as follows.

An in-cell touch panel according to a first configuration includes a plurality of thin film transistors, a plurality of source lines configured to respectively supply source signals to the plurality of thin film transistors, a source redundant line formed in the same layer as the plurality of source lines or a layer above the plurality of source lines and connected to at least one of the plurality of source lines, a touch sensor line formed in the same layer as either the plurality of source lines or the source redundant line, an organic insulating layer formed in a layer above the source redundant line and above the touch sensor line, a plurality of pixel electrodes formed in a layer above the organic insulating layer, and a common electrode formed in a layer above the organic insulating layer, and configured to function as a touch electrode and also function as a counter electrode that forms an electrical field together with the plurality of pixel electrodes, in which a contact hole in which part of the common electrode is arranged is formed in the organic insulating layer above the touch sensor line, and the common electrode is connected to the touch sensor line via the contact hole (first configuration).

According to the first configuration described above, the touch sensor line is formed in the same layer as the plurality of source lines or the source redundant line, so the touch sensor line and the plurality of source lines or the source redundant line can be formed in the same step. As a result, even when the source redundant line is formed, the number of manufacturing steps does not increase (the number of masks does not increase). Here, when the touch sensor line and the pixel electrode are formed in the same layer, it is necessary to secure a relatively large insulating distance between the touch sensor line and the pixel electrode in the plane direction. In contrast, according to the above first configuration, the touch sensor line is arranged in the layer (different layer) below the pixel electrode, so the distance between the touch sensor line and the pixel electrode in the plane direction can be reduced. Thus, the light blocking portion arranged between the pixel electrodes can be reduced in a plan view, so the aperture ratio of the in-cell touch panel can be increased. In addition, by increasing the aperture ratio, the light transmittance of the in-cell touch panel is improved, so the in-cell touch panel can be made higher in definition and can be driven at a higher frequency.

In the first configuration, the source redundant line may be arranged in parallel to the touch sensor line in a plan view (second configuration).

According to the second configuration described above, the source redundant line and the touch sensor line do not intersect, so the source redundant line and the touch sensor line can be easily formed in the same layer.

In the first configuration, when the touch sensor line is formed in the same layer as the source redundant line, the touch sensor line may be arranged above a first source line of the plurality of source lines, and the source redundant line may be arranged above a second source line of the plurality of source lines (third configuration).

According to the third configuration described above, either the touch sensor line or the source redundant line is arranged above each source line. As a result, the dimension in the width direction of each source line can be reduced as compared with the case in which both the touch sensor line and the source redundant line are arranged above each source line. As a result, the light transmittance of the in-cell touch panel can be improved.

In the first or second configuration, when the touch sensor line is formed in the same layer as the source redundant line, a first touch sensor redundant line formed in the same layer as the plurality of source lines and connected to the touch sensor line may be further provided (fourth configuration).

According to the fourth configuration described above, even when the touch sensor line is disconnected, the first touch sensor redundant line can be used for touch detection. Further, the first touch sensor redundant line is formed in the same layer as the plurality of source lines, so the first touch sensor redundant line can be formed in the step of forming the plurality of source lines. As a result, the first touch sensor redundant line can be formed without increasing the number of steps for manufacturing the in-cell touch panel.

In any one of the first to fourth configurations, a second touch sensor redundant line may be further provided in the same layer as the touch sensor line and connected to the common electrode to which the touch sensor line is connected (fifth configuration).

According to the fifth configuration described above, even when the touch sensor line is disconnected, the second touch sensor redundant line can be used for touch detection. Further, since the plurality of touch sensor lines are connected to one common electrode, the dimension in the width direction of one touch sensor line can be reduced, and the dimension of the connection part (contact hole) between the touch sensor line and the common electrode can also be reduced. As a result, the light transmittance of the in-cell touch panel can be improved by reducing the width of each touch sensor line and the dimension of the connection part.

In the fifth configuration, the touch sensor line and the second touch sensor redundant line may be arranged adjacent to each other in a plan view (sixth configuration).

According to the sixth configuration described above, the touch sensor line and the second touch sensor redundant line can be easily connected as compared with the case in which the touch sensor line and the second touch sensor redundant line are arranged apart from each other.

In the fifth or sixth configuration, the touch sensor line may be connected to the common electrode at a plurality of locations, and the second touch sensor redundant line may be connected to the common electrode at a plurality of locations (seventh configuration).

According to the seventh configuration described above, the size of each connection part (contact hole) between the touch sensor line and the second touch sensor redundant line and the common electrode can be reduced, so the light transmittance of the in-cell touch panel can be improved.

The method for manufacturing an in-cell touch panel according to the eighth configuration includes forming a plurality of source lines that respectively supply source signals to a plurality of thin film transistors on a substrate, forming a source redundant line connected to at least one of the plurality of source lines, forming a touch sensor line in the same layer as the plurality of source lines in the forming of the plurality of source lines, or forming a touch sensor line in the same layer as the source redundant line in the forming of the source redundant line, forming an organic insulating layer in a layer above the touch sensor line and the source redundant line, forming a contact hole in the organic insulating layer above the touch sensor line, forming a plurality of pixel electrodes in a layer above the organic insulating layer, and forming a common electrode, which functions as a touch electrode and also functions as a counter electrode that forms an electrical field together with the plurality of pixel electrodes, in a layer above the organic insulating layer with at least part of the common electrode arranged in the contact hole (eighth configuration).

According to the eighth configuration described above, the touch sensor line and the plurality of source lines or the source redundant line can be formed in the same step, so the number of manufacturing steps does not increase even when the source redundant line is formed.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An in-cell touch panel comprising:
a plurality of thin film transistors;
a plurality of source lines configured to respectively supply source signals to the plurality of thin film transistors;
a source redundant line formed in the same layer as the plurality of source lines or a layer above the plurality of source lines and connected to at least one of the plurality of source lines;
a touch sensor line formed in the same layer as either the plurality of source lines or the source redundant line;
an organic insulating layer formed in a layer above the source redundant line and above the touch sensor line;
a plurality of pixel electrodes formed in a layer above the organic insulating layer; and
a common electrode formed in a layer above the organic insulating layer, and configured to function as a touch electrode and also function as a counter electrode that forms an electrical field together with the plurality of pixel electrodes,
wherein a contact hole in which part of the common electrode is arranged is formed in the organic insulating layer above the touch sensor line, and
the common electrode is connected to the touch sensor line via the contact hole.

2. The in-cell touch panel according to claim 1,
wherein the source redundant line is arranged in parallel with the touch sensor line in a plan view.

3. The in-cell touch panel according to claim 1,
wherein the touch sensor line is formed in the same layer as the source redundant line,
the touch sensor line is arranged above a first source line of the plurality of source lines, and
the source redundant line is arranged above a second source line of the plurality of source lines.

4. The in-cell touch panel according to claim 1,
wherein the touch sensor line is formed in the same layer as the source redundant line, the in-cell touch panel further including
a first touch sensor redundant line formed in the same layer as the plurality of source lines and connected to the touch sensor line.

5. The in-cell touch panel according to claim 1, further comprising:
a second touch sensor redundant line formed in the same layer as the touch sensor line and connected to the common electrode to which the touch sensor line is connected.

6. The in-cell touch panel according to claim 5,
wherein the touch sensor line and the second touch sensor redundant line are arranged adjacent to each other in a plan view.

7. The in-cell touch panel according to claim 5,
wherein the touch sensor line is connected to the common electrode at a plurality of locations, and
the second touch sensor redundant line is connected to the common electrode at a plurality of locations.

8. A method for manufacturing an in-cell touch panel, the method comprising:
forming a plurality of source lines that respectively supply source signals to a plurality of thin film transistors on a substrate;
forming a source redundant line connected to at least one of the plurality of source lines;
forming a touch sensor line in the same layer as the plurality of source lines in the forming the plurality of source lines, or forming a touch sensor line in the same layer as the source redundant line in the forming the source redundant line;
forming an organic insulating layer in a layer above the touch sensor line and the source redundant line;
forming a contact hole in the organic insulating layer above the touch sensor line;
forming a plurality of pixel electrodes in a layer above the organic insulating layer; and
forming a common electrode, which functions as a touch electrode and also functions as a counter electrode that forms an electrical field together with the plurality of pixel electrodes, in a layer above the organic insulating layer with at least part of the common electrode arranged in the contact hole.
